(19) United States
(12) Patent Application Publication
(10) Pub. No.: US 2024/0196698 A1
(43) Pub. Date: Jun. 13, 2024

(54) DISPLAY APPARATUS

(71) Applicant: LG Display Co., Ltd., Seoul (KR)

(72) Inventor: Sehwan PARK, Gyeonggi-do (KR)

(73) Assignee: LG Display Co., Ltd., Seoul (KR)

(21) Appl. No.: 18/527,462

(22) Filed: Dec. 4, 2023

(30) Foreign Application Priority Data
Dec. 7, 2022 (KR) 10-2022-0169679

(51) Int. Cl. H10K 59/80

(52) U.S. Cl. CPC H10K 59/8722; H10K 59/873; H10K 59/8791; H10K 59/8794

(57) ABSTRACT

A display apparatus includes a cover window, an adhesive member positioned on an upper surface of the cover window, a display panel positioned on the adhesive member, a guide holder positioned on an upper side of the display panel to cover the display panel, and the adhesive member extends outward from the display panel, thereby reducing the total number of components and processes, mitigating component deformation, and reducing thickness and bezel size.

### CROSS-REFERENCE TO RELATED APPLICATION

The present application claims priority to Korean Patent Application No. 10-2022-0169679 filed on Dec. 7, 2022, which is hereby incorporated by reference in its entirety.

### BACKGROUND

### Field of the Disclosure

The present disclosure relates to a display apparatus, and more particularly, to a display apparatus capable of reducing the total number of components and processes, mitigating component deformation, and reducing thickness and bezel size.

### Description of the Background

Recently, the rapid advance of the field of displays for representing electrical information signals visually has led to development of various display apparatuses with excellent performance in terms of compactness, lightweight, and low power consumption.

Liquid crystal display (LCD) apparatuses and organic light emitting display (OLED) apparatuses are represented examples of display apparatuses.

Such display apparatuses have widely been incorporated into automobiles recently. In particular, display apparatuses incorporated into automobiles require enhanced durability to withstand the vibrational environment associated with vehicle movement. Furthermore, in terms of the interior design of automobiles, there is a demand to minimize the bezel size of the display apparatus to achieve an aesthetically pleasing appearance.

### SUMMARY

Accordingly, the present disclosure is directed to a display apparatus that substantially obviates one or more of problems due to limitations and disadvantages described above.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

More specifically, the present disclosure is to provide a display apparatus capable of reducing the total number of components, shortening the manufacturing process, mitigating component deformation, and reducing thickness and bezel size.

To achieve these and other advantages and in accordance with the present disclosure, as embodied and broadly described, a display apparatus includes a cover window, an adhesive member positioned on the upper surface of the cover window, a display panel positioned on the adhesive member, and a guide holder positioned on an upper side of the display panel to cover the display panel, wherein the adhesive member may extend outward from the display panel.

According to the present disclosure, by extending the adhesive member beyond the display panel to allow the guide holder to be positioned on the frontside of the adhesive material, it is possible to eliminate the necessity of a separate adhesive member for bonding the guide holder and the cover window.

According to the present disclosure, by attaching the guide holder to the cover window without being protrude outward beyond cover window, it is possible to reduce the size of the bezel area.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a front view of a display apparatus according to an aspect of the present disclosure;

FIG. 2 is a cross-sectional view of a light-emitting device of a display panel according to an aspect of the present disclosure;

FIG. 3 is a rear view of a display apparatus according to an aspect of the present disclosure;

FIG. 4 is a rear perspective view of a display apparatus according to an aspect of the present disclosure;

FIG. 5 is a cross-sectional view taken along line B-B′ in FIG. 3;

FIG. 6 is an enlarged view of areas A1 and B2 in FIG. 3;

FIG. 7 is an enlarged view of areas A3 and B4 in FIG. 3;

FIG. 8 is a cross-sectional view taken along line B-B′ in FIG. 3 according to a comparative example of the present disclosure;

FIG. 9 is a cross-sectional view taken along line B-B′ in FIG. 3 according to another aspect of the present disclosure;

FIG. 10 is a cross-sectional view taken along line B-B′ in FIG. 3 according to another aspect of the present disclosure;

FIG. 11 is a cross-sectional view taken along line B-B′ in FIG. 3 according to an alternative example of FIG. 10; and

FIGS. 12 and 13 are cross-sectional views of a viewing angle control layer, illustrating a viewing angle control function in the first mode and second mode, respectively.

### DETAILED DESCRIPTION

Advantages and features of the present disclosure and methods of accomplishing the same may be understood more readily by reference to the following detailed description of embodiments and the accompanying drawings. The present disclosure may, however, be embodied in many different forms and should not be construed as being limited to the exemplary embodiments set forth herein; rather, these exemplary embodiments are provided so that the present disclosure will be thorough and complete and will fully convey the concept of the disclosure to those skilled in the art, and the present disclosure will only be defined by the appended claims.

The shapes, sizes, ratios, angles, numbers and the like illustrated in the drawings to describe embodiments of the present disclosure are merely exemplary, and thus, the present disclosure is not limited thereto. Throughout the specification, the same reference numerals refer to the same components. In addition, detailed descriptions of well-known technologies may be omitted in the present disclosure to avoid obscuring the subject matter of the present disclosure. When terms such as “comprises,” “has,” “includes,” and “is made up of” are used in this specification, it should be understood that unless “only” is specifically used, additional elements or steps may be included. Unless otherwise explicitly stated, when a component is expressed in the singular form, it is intended to encompass the plural form as well.

In interpreting the components, it is construed to include a margin of error even in the absence of explicit description.

When describing the positional relationship, for example, when the relationship between two parts is described as “on”, “on top of”, “underneath”, “beside”, etc., unless “directly” or “immediately” is used, one or more other parts may be located between the two parts.

When a device or layer is referred to as being “on” another device or layer, it includes cases where one device or layer is directly located on the other device or layer or still other device or layer is interposed between the two devices or layers.

Although the terms “first”, “second”, and the like are used to describe various components, these components are not limited by these terms. These terms are merely used for distinguishing one component from the other components. Therefore, the first component mentioned hereinafter may be the second component in the technical sense of the present disclosure.

Throughout the specification, the same reference numerals refer to the same components.

The sizes and thicknesses of each component shown in the drawings are presented for the convenience of description and are not intended to limit the present disclosure.

The features of various embodiments of the present disclosure may be combined or assembled, either partially or entirely, in various technical manners such as interlocking and interoperations obvious to those skilled in the art, and each aspect may be independently implemented or in conjunction with related embodiments.

Hereinafter, detailed descriptions are made of the embodiments of the present disclosure with reference to the accompanying drawings.

In the present disclosure, the term “display apparatus” is used in a narrow sense to refer to display apparatuses, such as a liquid crystal module (LCM), an organic light-emitting diode (OLED) module, and a quantum dot (QD) module, each including a display panel and a panel driving unit to operate the display panel. In addition, the term may also be used to refer to set electronic devices, set devices, or apparatuses that include LCMs, OLED modules, QD modules, and the like, such as equipment display apparatuses including complete or final products such as laptop computers, televisions, computer monitors, automotive displays and equipment displays provided in other forms for vehicles, as well as mobile electronic devices such as smartphones and electronic pads.

Accordingly, in the present disclosure, the display apparatus may include not only the display apparatuses in the narrow sense, such as LCMs, OLED modules, QD modules, but also set devices as application products or final consumer devices each including LCMs, OLED modules, QD modules, and the like.

Additionally, in some cases, an LCM, an OLED module, or a QD module, composed of a display panel and a panel driving unit may be referred to as “display apparatus” in a narrow sense, while an electronic device as a complete product including an LCM, an OLED module, or a QD module may be referred to as “set device”. For example, the narrow-sense display apparatus may include a display panel of liquid crystal (LCD), organic light-emitting diode (OLED), or quantum dot and a source printed circuit board (PCB) as a control unit for driving the display panel, while a set device may be a concept that further includes a set PCB, serving as a set control unit that is electrically connected to the source PCB and controls the entire set device.

The display panel used in the embodiments may include all types of display panels such as liquid crystal display panels, organic light-emitting diode (OLED) display panels, quantum dot (QD) display panels, and electroluminescent display panels, and is not limited to a specific display panel capable of bending a bezel with a flexible substrate for OLED display panel and a backplate support structure thereunder. In addition, the display panel used in the aspect of the present disclosure is not limited to the shape or size of the display panel.

For example, when the display panel is an organic light-emitting diode (OLED) display panel, it may include a plurality of gate lines and data lines and pixels formed at the intersection of the gate lines and data lines. In addition, it may be configured to include an array including thin-film transistors as components for selectively applying a voltage to each pixel, an organic light-emitting diode (OLED) layer on the array, an encapsulation substrate or encapsulation layer arranged on the array to cover the organic light-emitting diode layer, etc.

The encapsulation layer may protect the thin film transistors and the organic light-emitting device layer from external impacts and prevent moisture or oxygen from penetrating into the organic light-emitting device layer. In addition, the layers formed on the array may include an inorganic light-emitting layer, such as a nano-sized material layer and quantum dots.

In the present disclosure, the display panel is an exemplary organic light-emitting diode (OLED) display panel that may be integrated within display apparatuses.

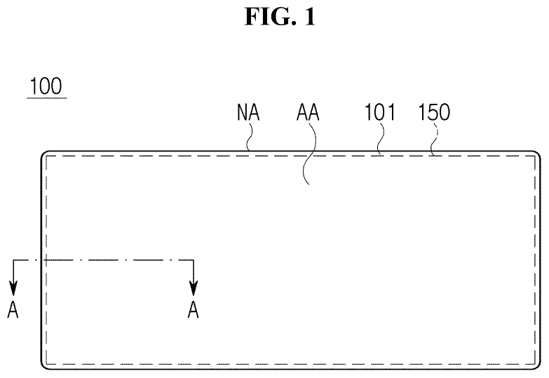

FIG. 1 is a diagram illustrating a display apparatus 100 according to an aspect of the present disclosure.

With reference to FIG. 1, the display apparatus 100 may be applied to televisions (TVs), monitors, personal computers (PCs), center consoles in vehicles, etc. Although FIG. 1 shows a substantially rectangular display panel 150, the shape of the display apparatus 100 is not necessarily limited thereto and may be manufactured in various forms, including square, polygonal, or curved shapes.

With reference to FIG. 1, the display apparatus 100 includes a cover window 101 and a display panel 150. The cover window 101, as a means of protecting the display panel 150 from external impact, may be formed of materials such as glass and plastic.

The display panel 150 is positioned on the backside of the cover window 101 and may be bonded to the cover window 101 through an adhesive member. The display panel 150 may include a polarizing plate, a panel layer, and a touch panel. Particularly in the case of a display panel 150 is installed in a car, a viewing angle control film may be added to control the light emitted towards the driver's side, aiming to control the viewing angle. The viewing angle control film is a specialized form suitable for the display apparatus 100 installed in a vehicle. Especially in recent vehicles, the display apparatus 100 is positioned in front of the driver's seat to display information such as the speedometer, in the center to display navigation, and in front of the passenger seat to provide a multimedia display for the occupant of the front passenger seat. Furthermore, in recent times, the display apparatus 100 has been formed as a unified unit spanning across the front of the driver's seat, the center, and the front of the passenger seat. Therefore, the viewing angle control film is essential to prevent the display of images intended for the front passenger from being visible to the driver.

The display apparatus 100 includes a display area AA on the front where users may view videos or images, as well as a non-display area NA where images are not shown. The non-display area NA may also be referred to as the bezel area.

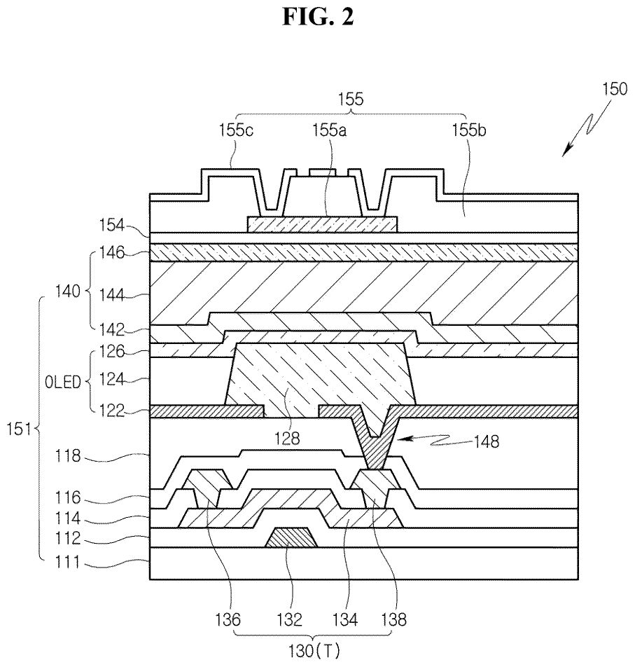

FIG. 2 is a cross-sectional view of a light-emitting device of a display panel according to an aspect of the present disclosure.

With reference to FIG. 2, a substrate 111 is positioned at the bottommost side of the display panel 150. The substrate 111 may support various components of the display panel 150. The substrate 111 may be formed of a transparent dielectric material such as glass, plastic, and the like. In the case of being made of plastic, the substrate 111 may be a plastic film or a plastic substrate. For example, the substrate 111 may take the form of a film including one of the polyimide-based polymers, polyesters-based polymers, silicone-based polymers, acrylic-based polymers, polyolefin-based polymers, and their copolymers. Among these materials, polyimide is mainly used as a plastic substrate because it is suitable for high-temperature processes and is a material that may be coated.

A buffer layer may be positioned on the substrate 111. The buffer layer is a functional layer that protects the thin film transistor (TFT) from impurities such as alkali ions that may leak from the bottom of the substrate 111. The buffer layer may be formed of silicon oxide (SiOx), silicon nitride (SiNx), or multiple layers thereof.

A thin film transistor 130 may be disposed on the buffer layer. The thin film transistor 130 may be formed by sequentially arranging a gate electrode 132, a gate insulating layer 112, a semiconductor layer 134, an interlayer insulating film 114, and source and drain electrodes 136 and 138 on the buffer layer. There may be one or more thin film transistors 130 arranged for a plurality of sub-pixels provided in the active area.

Although illustrated as the bottom-gate type in FIG. 2, the thin film transistor 130 is not limited thereto and may also be provided as the top-gate type, in which the order of the semiconductor layer 134 and the gate electrode 132 is reversed.

The semiconductor layer 134 may be arranged at a specific portion on the substrate 111 or on the buffer layer. The semiconductor layer 134 may be made of polycrystalline silicon (p-Si), and in this case, a region of the semiconductor layer 134 may be doped with impurities to form the electrode layer. The semiconductor layer 134 may also be made of amorphous silicon (a-Si) and various organic semiconductor materials such as pentacene. Furthermore, the semiconductor layer 134 may also be made of an oxide material. The gate insulating layer 112 may be formed of inorganic insulating materials such as silicon oxide (SiOx) and silicon nitride (SiNx) and, as well, organic insulating materials. The gate electrode 132 may be formed of various conductive materials, such as magnesium (Mg), aluminum (Al), nickel (Ni), chromium (Cr), molybdenum (Mo), tungsten (W), and gold (Au), or alloys thereof.

The first interlayer insulating film 114 may be formed of inorganic insulating materials such as silicon oxide (SiOx) and silicon nitride (SiNx) and, as well, organic insulating materials. The first interlayer insulating film 114 may be selectively removed to form contact holes exposing the source and drain regions.

The source and drain electrodes 136 and 138 are formed as a single layer or multilayer of electrode material on the first interlayer insulating film 114.

An inorganic protective film 116 and a planarization layer 118 may be positioned on the thin film transistor 130 to cover the source and drain electrodes 136 and 138. The inorganic protective film 116 and the planarization layer 118 protect the thin film transistor 130 and flatten its upper surface.

The inorganic protective film 116 may be formed of inorganic insulating films such as silicon nitride (SiNx) and silicon oxide (SiOx), while the planarization layer 118 may be made of organic insulating films such as benzocyclobutene (BCB) and acrylic (Acryl). The inorganic protective film 116 and the planarization layer 118 may each be formed as a single layer, dual-layer, or multilayer structure, and in some cases, one of the two layers may be omitted.

A light-emitting component OLED connected to the thin film transistor (TFT) 130 may be formed by sequentially arranging a first electrode 122, an organic light-emitting layer 124, and a second electrode 126. That is, the light-emitting component OLED may be composed of the first electrode 122 connected to the drain electrode 138 through the via hole 148 formed in the planarization layer 118 and the inorganic protective film 116, the organic light emitting layer 124 position on the first electrode 122, and the second electrode 126 positioned on the organic light-emitting layer 124.

When the display panel 150 is of a top emission type where the emission occurs upward through the second electrode 126, the first electrode 122 may include an opaque conductive material with high reflectivity. In this case, examples of the reflective conductive material may include silver (Ag), aluminum (Al), gold (Au), molybdenum (Mo), tungsten (W), chromium (Cr), or alloys thereof.

A bank 128 is formed in the area excluding the light-emitting area, opening the light-emitting area. Accordingly, the bank 128 has a bank hole exposing the first electrode 122 corresponding to the light-emitting area. The bank 128 may be made of inorganic insulating materials such as silicon nitride (SiNx), silicon oxide (SiOx), or organic insulating materials such as BCB, acrylic-based resins and imide-based resins.

The organic light-emitting layer 124 is positioned on the first electrode 122 exposed by the bank 128. The organic light-emitting layer 124 may include a hole injection layer, a hole transport layer, an emissive layer, an electron transport layer, and an electron injection layer. In addition, the organic light-emitting layer 124 may be composed of a single emissive layer structure that emits a single light within a single stack, or a multi-stack structure including multiple stacks, each of which includes a single emissive layer of the same color. In such cases, adjacent sub-pixels may be arranged to emit different colors of light to display various colors. For example, sub-pixels with emissive layers of red, green, and blue may be arranged in a row or spaced apart from each other and, as well, in a triangle shape or pentile structure with some sub-pixels of predetermined colors aligned parallel and others aligned diagonally to each other.

In some cases, sub-pixels of white color may also be added to the arrangement. In addition, the organic light-emitting layer 124 may be configured by stacking a plurality of stacks including emissive layers emitting different colors of light to express white. In the case of expressing white with a stacked structure, separate color filters may be additionally added to each sub-pixel.

The second electrode 126 is positioned on the organic light-emitting layer 124. When the display panel 150 adopts a top emission structure, the second electrode 126 may be formed of a transparent conductive material such as indium tin oxide (ITO) and indium zinc oxide (IZO) and a semi-transparent metal or metal alloy such as MgAg to emit light generated in the organic light-emitting layer 124 upward through the second electrode 126.

The second electrode 126 may be arranged to reach a capping layer (not shown) of the to. The capping layer may protect the OLED and assist in the extraction of light emitted through the second electrode 126 by using a material with a high refractive index.

An encapsulation layer 140 may be disposed on the light-emitting component OLED. The encapsulation layer 140 prevents the infiltration of oxygen and moisture from the outside to prevent oxidation of the emissive and electrode materials. Exposure of OLED to moisture or oxygen may cause pixel shrinkage or the formation of dark spots, reducing the emitting area. The encapsulation layer 140 is formed by alternately stacking inorganic layers 142 and 146 made of glass, metal, aluminum oxide (AlOx), or silicon (Si) materials and an organic layer 144 that serves as a buffer relieving the stress between layers due to the bending of the display panel (100 in FIG. 1) and enhances the flattening performance. The organic layer 144 may be made of organic insulating materials such as acrylic resin, epoxy resin, polyimide, polyethylene, and silicon oxycarbide (SiOC). Here, the first and second inorganic layers 142 and 146 serve to block the penetration of moisture or oxygen, while the organic layer 144 flattens the surface of the first inorganic layer 142. The encapsulation layer 140 is composed of several thin film layers to increase the length and complexity of the path that moisture and oxygen must travel compared to a single layer, with the purpose of making it difficult for moisture and oxygen to penetrate to the light-emitting component OLED.

A protective layer (not shown) may be formed further between the light-emitting component OLED and the encapsulation layer 140 to protect the encapsulation layer 140 from being peeled off or affecting the uniformity during the manufacturing process of the encapsulation layer 140.

With reference to FIG. 2, a polarization layer 154 may be disposed on the encapsulation layer 140. The polarization layer 154 may minimize the impact of light entering the display panel 150 from external light sources on the semiconductor layer 134 or the organic light-emitting layer 124.

With reference to FIG. 2, a touch sensor layer 155 may be arranged on the polarization layer 154. The touch sensor layer 155 may be structured with the first touch electrode 155a and the second touch electrode 155c intersecting each other, allowing one electrode to receive an applied voltage signal and the other to sense the voltage signal. The first touch electrode 155a and the second touch electrode 155c may be patterned into polygonal or circular shapes on a touch insulation layer 155b to be arranged at a distance from each other.

The front cover member 101 may be disposed on the touch sensor layer 155. The touch sensor layer 155 and the front cover member 101 may be bonded together via an adhesive layer interposed therebetween.

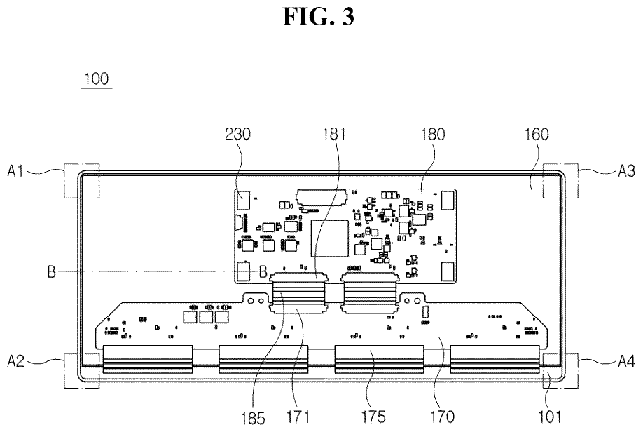

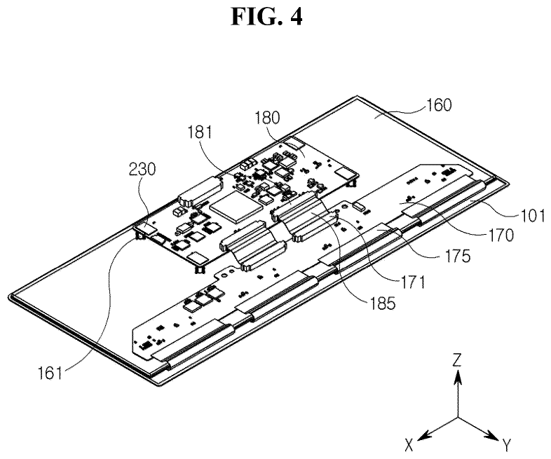

FIG. 3 is a rear view of a display apparatus according to an aspect of the present disclosure. FIG. 4 is a rear perspective view of a display apparatus according to an aspect of the present disclosure.

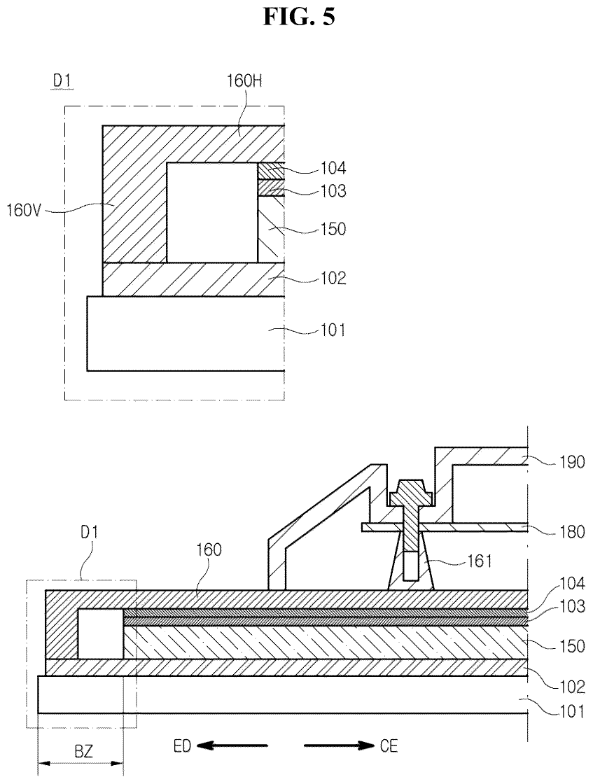

In FIG. 3, it is depicted that the guide holder 160 covers the cover window 101 positioned at the bottom as viewed from the perspective facing the rear side of the display apparatus 100. However, as shown in cross-sectional views of FIG. 5, other components such as an adhesive member 102, display panel 150, backplate 103, and heat dissipation plate 104 may be positioned between the cover window 101 and the guide holder 160. Considering that the components have a very thin thickness in millimeters, these components are omitted in the rear view of FIG. 3 and the rear perspective view of FIG. 4. In addition, as shown in the cross-sectional view of FIG. 5, a back cover 190 may be positioned on top of the guide holder 160. To provide a detailed description of the rear side of the display apparatus 100, the back cover 190 is omitted in the illustrations. The description based on FIGS. 3 and 4 may be made with reference to FIG. 5.

According to an aspect of the present disclosure, the display apparatus 100 may include a cover window 101, a guide holder 160, a source printed circuit board 170, and a control printed circuit board 180.

The cover window 101 may be positioned on the front of the display panel 150 and may be made of a high-strength glass material, but is not limited thereto. The cover window 101 may include an active area (AA in FIG. 1) and an inactive area (NA in FIG. 1). The active area AA may correspond to the area of the display panel 150, while the non-active area NA may correspond to the bezel area.

The guide holder 160 may be positioned on the upper surface of the display panel 150. In an aspect of the present disclosure, the guide holder 160 may be made of a high thermal conductivity material such as aluminum, but is not limited thereto. For example, it may be made of a synthetic metal material that includes magnesium. The guide holder 160 may also be made of plastic material.

The guide holder 160 may be adhered to the rear side of the display panel 150. Accordingly, the guide holder 160 may serve as a heat sink to dissipate and remove the heat generated by the display panel 150.

The guide holder 160 is also designed to serve to fix the source printed circuit board 170 and the control printed circuit board 180 in place. For example, the guide holder 160 may include board support blocks 161, and the control printed circuit board 180 may be positioned on top of the board support blocks 161. The board support blocks 161 may be arranged in multiple quantities.

The source printed circuit board 170 may be positioned on the rear side of the guide holder 160 and connected to the display panel 150 via a flexible circuit board 175. The flexible circuit board 175 may take the form of a chip-on-film (COF) incorporating source driver ICs.

The control printed circuit board 180 may be positioned on the board support block 161 formed on the guide holder 160 and connected to the source printed circuit board 170 via a flat cable 185. In detail, the flat cable 185 connects the first connector 171 positioned on the source printed circuit board 170 and the second connector 181 positioned on the control printed circuit board 180 for the control printed circuit board 180 to control the source printed circuit board 170.

The back cover member 190 may be positioned on and coupled, via screws as an example, to the upper surface of the guide holder 160 to enclose and protect the source printed circuit board 170 and the control printed circuit board 180. The back cover member 190 may be made of a synthetic metal material including magnesium (Mg) or polycarbonate (PC) material, but is not necessarily limited thereto. For example, the back cover 190 may be made of plastic material.

FIG. 5 is a cross-sectional view taken along the line B-B′ in FIG. 3. A description is made the display apparatus 100 according to an aspect of the present disclosure with reference to FIG. 5.

The display apparatus 100 is equipped with a cover window 101 positioned at the bottommost side. An adhesive member 102 is positioned on the upper side of the cover window 101.

The adhesive member 102 serves to bond the cover window 101 and the display panel 150 together. The adhesive member 102 may be a transparent material, such as optical clear adhesive (OCA) and pressure sensitive adhesive (PSA), for example.

The display panel 150 is positioned on the upper side of the adhesive member 102. The display panel 150 emits light to display images or graphics and includes a plurality of pixels and transistors to drive the pixels internally. The detailed structure of the display panel 150 has been described as an example with reference to FIG. 2.

A backplate 103 is positioned on the upper side of the display panel 150. The backplate 103 may serve as a rigid structure reinforcing the rigidity of the display panel 150. The backplate 103 may be formed as a thin plastic film.

A heat dissipation plate 104 is positioned on the upper side of the backplate 103. The heat dissipation plate 104 serve to dissipate the heat generated by the display panel 150 or the source printed circuit board 170 and the control printed circuit board 180. The heat dissipation plate 104 may be made of metal materials such as aluminum, magnesium and plastic materials with high thermal conductivity.

A guide holder 160 is positioned on the upper side of the heat dissipation plate 104. The guide holder 160 may serve to protect the underlying components and support the control printed circuit board 180. The guide holder 160 may include board support blocks 161 to support the control printed circuit board 180. The guide holder 160 may be made of metal or plastic material.

A back cover 190 may be positioned on the upper side of the guide holder 160. The back cover 190 may serve to protect the underlying source printed circuit board 170 and the control printed circuit board 180. The back cover 190 may be attached to the guide holder 160 using screws. The back cover 190 may be made of metal or plastic material.

In this aspect, the edge direction ED refers to the direction toward the edges of the display apparatus 100. For example, the edge direction ED refers to the direction from the center of the display apparatus 100 towards the non-display area NA (see FIG. 1), while the center direction CE refers to the direction towards the center of the display apparatus 100. For example, the center direction CE refers to the direction from the non-display area NA (see FIG. 1) towards the display area AA of the display apparatus 100.

In this aspect, the cover window 101 may protrude more outward compared to the adhesive member 102. Conversely, the adhesive member 102 may be retreated more inward compared to the cover window 101.

In this aspect, the adhesive member 102 may protrude more outward in the edge direction compared to the display panel 150. Conversely, the display panel 150 may retreat more inward in the edge direction compared to the adhesive member 102. In other words, the adhesive member 102 is formed to extend more outward in the edge direction from the display panel 150.

In this aspect, the guide holder 160 may be in contact with an upper part of the adhesive member 102. With reference to the enlarged view D1 in FIG. 5, the guide holder 160 may include a horizontal portion 160H and a vertical portion 160V. The lower part of the vertical portion 160V may come into contact with the upper part of the adhesive member 102. Although the guide holder 160 was depicted as a rectangular shape with horizontal portion 160H and vertical portion 160V for convenience of the explanation, the guide holder 160 may have a curved shape as well. In the case, the portion of the guide holder that comes into contact with the adhesive member 102 may correspond to the vertical portion 160V, and the portion of the guide holder that covers the upper side of the display panel 150 may correspond to the horizontal portion 160H.

In this aspect, the vertical portion 160V of the guide holder 160 is spaced apart from the display panel 150.

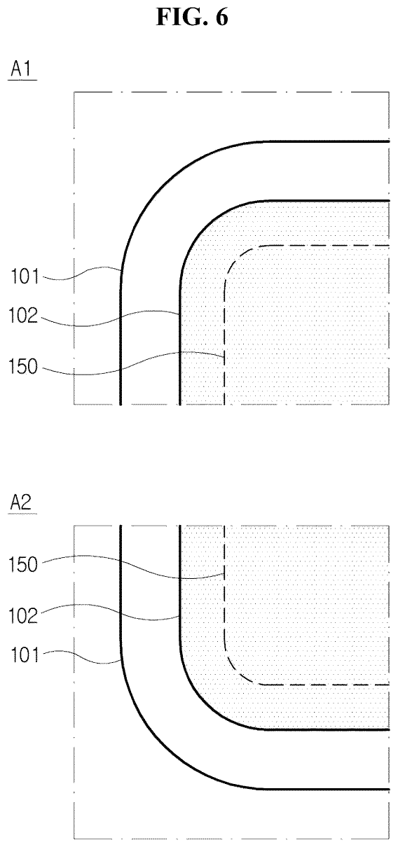

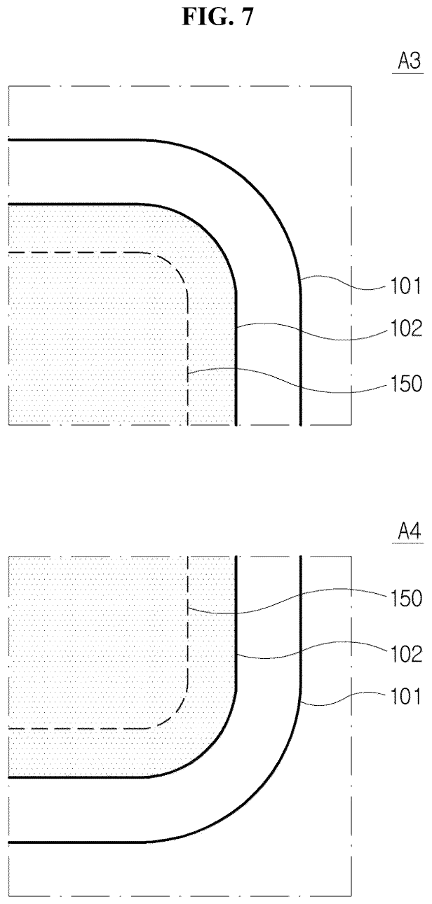

The positional relationship between the cover window 101, adhesive member 102, and display panel 150 according to this aspect is described in more detail with reference to FIGS. 6 and 7.

FIGS. 6 and 7 are enlarged views of areas A1, A2, A3, and A4 from FIG. 3. That is, FIGS. 6 and 7 are enlarged views of the four corner portions of the display apparatus 100 that are corresponding or symmetrical in shape.

Observing area A1 in FIG. 6, the cover window 101 protrudes the furthest outward. The adhesive member 102 is retreated inward compared to the cover window 101, but protrudes outward compared to the display panel 150. The display panel 150 is retreated the most inward. That is, when observed from the rear side of the display apparatus 100, the adhesive member 102 may be visible between the edges of the cover window 101 and the display panel 150.

The description for area A2 in FIG. 6 is the same as the description for the area A1 in FIG. 6. The descriptions for areas A3 and A4 in FIG. 7 are the same as the description for area A1 in FIG. 6.

FIG. 5 is referred back for description.

According to an aspect, the adhesive member 102 protrudes outward from the display panel 150, allowing the guide holder 160 to be directly secured by the adhesive member 102. For example, when the adhesive member 102 is retreated inward compared to the display panel 150, then a separate adhesive may be required for the vertical portion 160V of the guide holder 160 to be attached to the cover window 101. In this aspect, however, by extending the adhesive member 102 more outward to provide a sufficient area for the guide holder 160 to be attached. As a result, this aspect may simplify the process of manufacturing the display apparatus 100.

Also, by attaching the guide holder 160 to the upper side of the cover window 101, the guide holder 160 does not protrude more outward than the cover window 101. As a result, the display apparatus 100 manufactured according to this aspect may have a reduced bezel size.

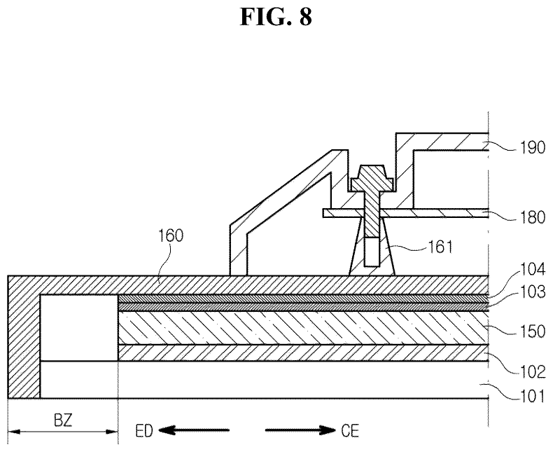

FIG. 8 is a cross-sectional view taken along the line B-B′ in FIG. 3 according to a comparative example of the present disclosure. A description is made of a comparative example of the present disclosure with reference to FIG. 8.

With reference to FIG. 8, it may be observed that the adhesive member 102 is retreated more inwards compared to the display panel 150. That is, the adhesive member 102 does not protrude more outward than the display panel 150. Accordingly, the guide holder 160 cannot be attached to the upper side of the cover window 101. When it is intended to attach the guide holder 160 to the upper side of the cover window 101, a separate adhesive member (not shown) would need to be placed on the upper side of the edge of the cover window 101. That would result in an additional manufacturing process.

When the adhesive member 102 is not extended more outward than the display panel 150 as shown in FIG. 8, the guide holder 160 may be attached to the side of the cover window 101. To attach the guide holder 160 to the side of the cover window 101, a separate adhesive member (not shown) may need to be placed, resulting in an additional manufacturing process. In this case, the portion where the guide holder 160 protrudes more outward than the cover window 101 may add to the bezel BZ. As a result, the bezel BZ of the display apparatus 100 increases.

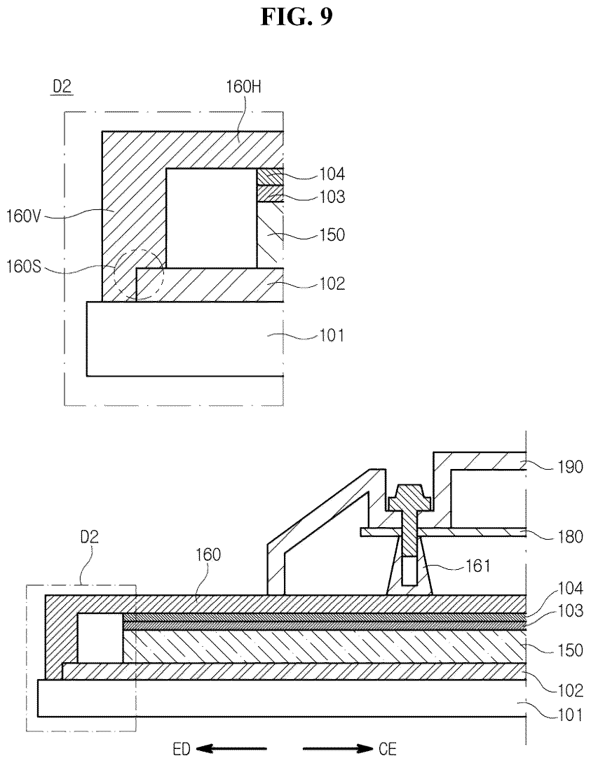

FIG. 9 is a cross-sectional view taken along the line B-B′ in FIG. 3 according to another aspect of the present disclosure. A description is made of another aspect of the present disclosure with reference to FIG. 9.

The display apparatus 100 is equipped with a cover window 101 positioned at the bottommost side. The adhesive member 102 serves to bond the cover window 101 and the display panel 150 together. The display panel 150 is positioned on the upper side of the adhesive member 102. A backplate 103 is positioned on the upper side of the display panel 150. A heat dissipation plate 104 is positioned on the upper side of the backplate 103. A guide holder 160 is positioned on the upper side of the heat dissipation plate 104. A back cover 190 is positioned on the upper side of the guide holder 160.

The detailed description of the cover window 101, adhesive member 102, display panel 150, backplate 103, heat dissipation plate 104, guide holder 160, and back cover 190 are the same as previously described.

In this aspect, the definitions of the edge direction ED and center direction CE are the same as previously described.

In this aspect, the cover window 101 protrudes more outward compared to the adhesive member 102. In this aspect, the adhesive member 102 protrudes more outward compared to the display panel 150. In other words, the adhesive member 102 is formed to extend more outward from the display panel 150.

In this aspect, the guide holder 160 may be in contact with an upper side of the adhesive member 102.

With reference to the enlarged view D2 in FIG. 9, the guide holder 160 may include a horizontal portion 160H, a vertical portion 160V, and a stepped portion 160S. As shown in the enlarged view D2 of FIG. 9, the stepped portion 160S may have a stepped shape. The stepped portion 160S may be in contact with the upper side of the cover window 101. The stepped portion 160S may also come into contact in part with the adhesive member 102. Compared to the aspect of FIG. 5, the guide holder 160 comes in to contact with the cover window 101 and the adhesive member 102 through the stepped portion 160S, which increases the contact area, leading to the enhancement of the adhesive strength.

In this aspect, the vertical portion 160V of the guide holder 160 is spaced apart from the display panel 150.

According to this aspect, the adhesive member 102 protrudes more outward than the display panel 150, allowing the guide holder 160 to be directly secured by the adhesive member 102. As a result, the manufacturing process may be further simplified. The process of applying a separate adhesive material for bonding the guide holder 160 and the cover window 101 may be eliminated. Therefore, the manufacturing process may be further simplified.

According to this aspect, by bonding the guide holder 160 to the upper side of the cover window 101, the guide holder 160 does not protrude more outward than the cover window, allowing for the reduction of the bezel area of the display apparatus 100.

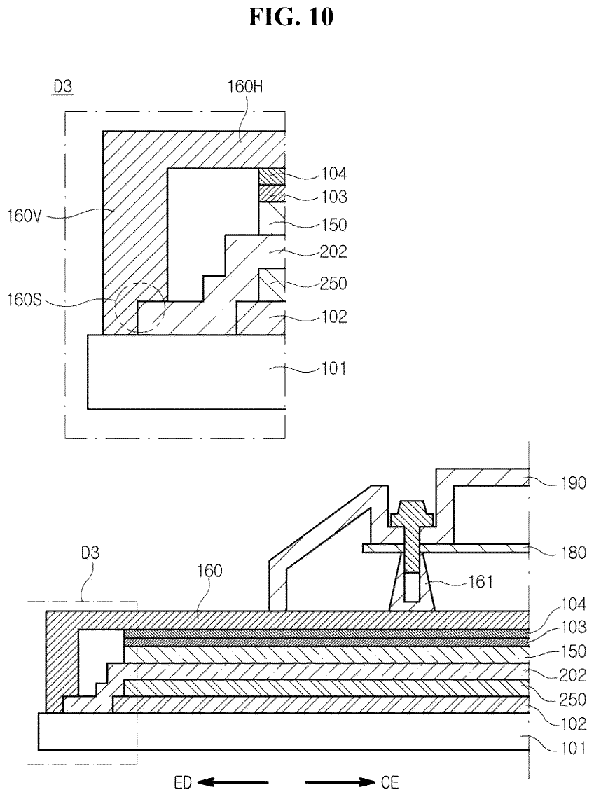

FIG. 10 is a cross-sectional view taken along the line B-B′ in FIG. 3 according to another aspect of the present disclosure. A description is made of another aspect of the present disclosure with reference to FIG. 10.

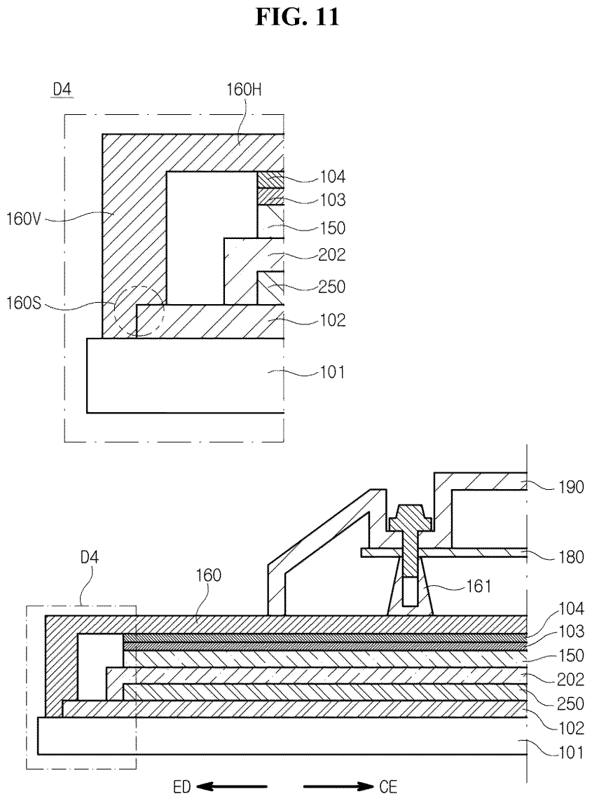

FIG. 11 is a cross-sectional view taken along the line B-B′ in FIG. 3 according to an alternative example of FIG. 10. An alternative example of the aspect of FIG. 10 is described with reference to FIG. 11.

The display apparatus 100 is equipped with a cover window 101 positioned at the bottommost side. An adhesive member 102 is positioned on the upper side of the cover window 101.

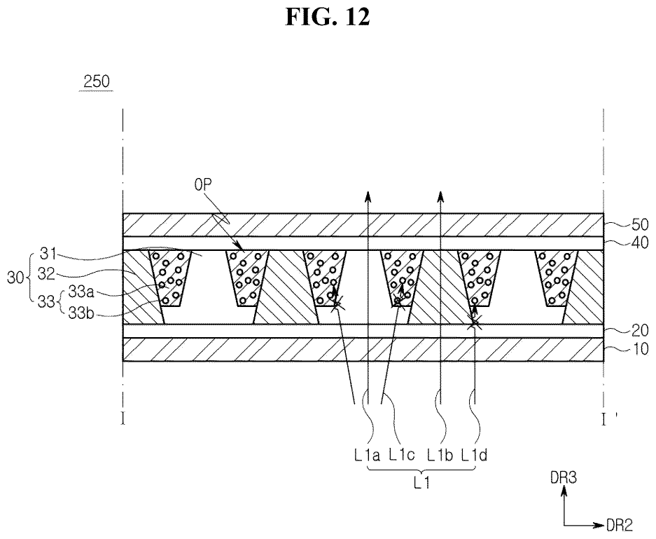

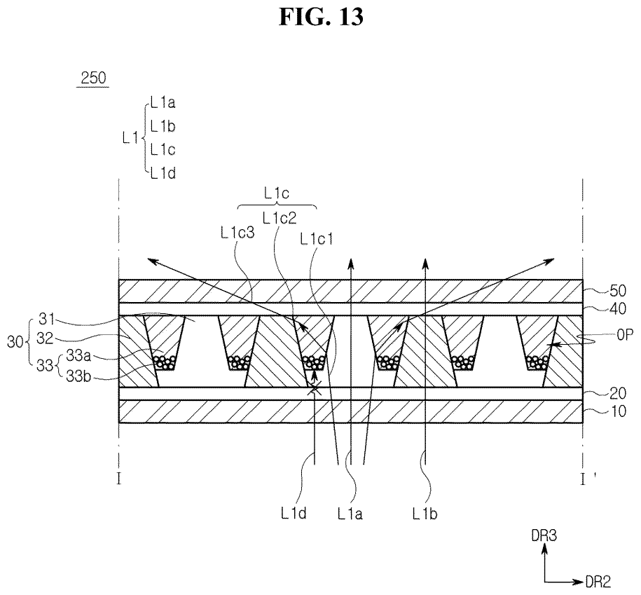

This aspect differs from the previous aspect in that a viewing angle control layer 250 is arranged on the adhesive member 102. The viewing angle control layer 250 is responsible for controlling the direction of light emitted from the display panel 150 and may be positioned on the front surface of the display panel 150. In particular, the display apparatus 100 installed in a vehicle needs to be selectively controlled to emit light or not emit light to the driver. The viewing angle control layer 250 may selectively control the path of light emitted from the display panel 150 in this way. The viewing angle control layer 250 will be described later in detail with reference to FIGS. 12 and 13.

With reference back to FIG. 10, a second adhesive member 202 is positioned on the viewing angle control layer 250. The second adhesive member 202 serves to bond the viewing angle control layer 250 and the display panel 150 together. The second adhesive member 202 serves to attaching the viewing angle control layer 250 to the display panel 150.

The display panel 150 is positioned on the upper side of the adhesive member 202. A backplate 103 is positioned on the upper side of the display panel 150. A heat dissipation plate 104 is positioned on the upper side of the backplate 103. A guide holder 160 is positioned on the upper side of the heat dissipation plate 104. A back cover 190 is positioned on the upper side of the guide holder 160.

The detailed description of the cover window 101, adhesive member 102, display panel 150, backplate 103, heat dissipation plate 104, guide holder 160, and back cover 190 are the same as previously described.

In this aspect, the definitions of the edge direction ED and center direction CE are the same as previously described.

In this aspect, the cover window 101 protrudes more outward compared to the adhesive member 102. In this aspect, the adhesive member 102 protrudes more outward compared to the display panel 150. In other words, the adhesive member 102 is formed to extend more outward from the display panel 150.

In this aspect, the second adhesive member 202 may protrude more outward compared to the display panel 150. In other words, the second adhesive member 202 is formed to extend more outward from the display panel 150.

Furthermore, the adhesive member 102 and the second adhesive member 202 protrude more outward compared to the viewing angle control layer 250. That is, the adhesive member 102 and the second adhesive member 202 are formed to extend further outward from the viewing angle control layer 250.

In this aspect the guide holder 160 may be in contact with an upper side of the second adhesive member 202.

With reference to the enlarged view D3 in FIG. 10, the guide holder 160 may include a horizontal portion 160H, a vertical portion 160V, and a stepped portion 160S. As shown in the enlarged view D3 of FIG. 10, the stepped portion 160S may have a stepped shape. The stepped portion 160S may be in contact with the upper side of the cover window 101. The stepped portion 160S may also come into contact in part with the second adhesive member 202. Compared to the aspect of FIG. 5, the guide holder 160 comes contact with the cover window 101 and the second adhesive member 202 through the stepped portion 160S, which increases contact area, leading to the enhancement of the adhesive strength.

Furthermore, as an alternative example of FIG. 10, the adhesive member 102 may extend further outward than the second adhesive member 202, unlike what is shown in FIG. 11. In the alternative example, with reference to the enlarged view D4 in FIG. 11, the stepped portion 160S may come into contact in part with the upper side of the cover window 101. The stepped portion 160S may also come into contact in part with the upper side of the adhesive member 102. In the alternative example of FIG. 11, the guide holder 160 may come into contact with the upper side of the cover window 101, the upper side of the adhesive member 102, and the lateral side of the second adhesive member 202.

In the embodiments of FIGS. 10 and 11, the vertical portion 160V of the guide holder 160 and the display panel 150 are spaced apart from each other.

According to the embodiments of FIG. 10 and FIG. 11, the adhesive member 102 or the second adhesive member 202 may protrude further outward than the display panel 150, allowing the guide holder 160 to be directly secured by the adhesive member 102 or the second adhesive member 202. As a result, the manufacturing process may be further simplified. The process of applying a separate adhesive material for bonding the guide holder 160 and the cover window 101 may be eliminated. Therefore, the manufacturing process may be further simplified. In particular, in the alternative example of FIG. 11, the guide holder 160 may also come into contact with the lateral side of the second adhesive member 202 compared to the aspect of FIG. 10, which may enhance the fixation strength.

According to this embodiments of FIGS. 10 and 11, by bonding the guide holder 160 to the upper side of the cover window 101, the guide holder 160 does not protrude more outward than the cover window 101, allowing for the reduction of the bezel area of the display apparatus 100.

FIGS. 12 and 13 are cross-sectional views of a viewing angle control layer 250, illustrating a viewing angle control function in the first mode and second mode, respectively.

The viewing angle control layer 250 may include a first substrate 10, a first electrode 20 on the first substrate 10, a light conversion portion 30 on the first electrode 20, a second electrode 40 on the light conversion portion 30, and a second substrate 50 on the second electrode 40. The light conversion portion 30 may be positioned between the first electrode 20 and the second electrode 40.

The first substrate 10 may support the first electrodes 20. The first substrate 10 may be rigid or flexible. In addition, the first substrate 10 may be transparent. For example, the first substrate 10 may include a transparent substrate capable of transmitting light. The first substrate 10 may include a glass, plastic, or flexible polymer film. In addition, the first substrate 10 may be a curved or bent substrate.

The first electrode 20 may be disposed on one surface of the first substrate 10. In more detail, the first electrode 20 may be disposed on the upper surface of the first substrate 10. That is, the first electrode 20 is interposed between the first substrate 10 and the second substrate 50. The first electrode 20 may include transparent conductive material. For example, the first electrode 20 may include metal oxides such as indium tin oxide, indium zinc oxide, copper oxide, tin oxide, zinc oxide, and titanium oxide, etc.

The second substrate 50 may be disposed on the first substrate 10. The second substrate 50 may face the first substrate 10. The second substrate 50 may include materials that are capable of transmitting light. The second substrate 50 may be made of transparent materials. The second substrate 50 may include the same or similar materials as the above-described first substrate 10. In addition, the second substrate 50 may be a flexible substrate with a flexible characteristic. In addition, the second substrate 50 may be a curved or bent substrate.

The second electrode 40 may be disposed on one surface of the second substrate 50. In more detail, the second electrode 40 may be disposed on lower surface of the second substrate 50. That is, the second electrode 40 may be positioned on the surface of the second substrate 50 facing the first substrate 10. That is, the second electrode 40 may be positioned facing the first electrode 20 on the first substrate 10. That is, the second electrode 40 may be interposed between the first electrode 20 and the second substrate 50. The second electrode 40 may include transparent conductive materials.

The light conversion portion 30 may be interposed between the first substrate 10 and the second substrate 50. In more detail, the light conversion portion 30 may be interposed between the first electrode 20 and the second electrode 40.

The light conversion portion 30 may include a light transmissive portion 31, a high refractive index portion 32 surrounding the light transmissive portion 31, and a transmittance variable portion 33 between the light transmissive portion 31 and the high refractive index portion 32. The transmittance variable portion 33 may vary the light transmittance depending on the applied voltage. The light transmissive portion 31 may be disposed between the adjacent high refractive index portions 32. The high refractive index portion 32 may be disposed between the light transmissive portions 31.

For example, the cross-section of the high refractive index portions 32 may take a trapezoidal shape. That is, the width of the upper surface of the high refractive index portions 32 may be smaller than the width of the lower surface. However, the cross-section of the high refractive index portion 32 is not limited the aforementioned shape and may take an inverted trapezoidal, rectangular, square, or other polygonal shape. For example, the cross-section of the transmittance variable portion 33 may take an inverted trapezoidal shape. That is, the width of the top surface of the transmittance variable portion 33 may be larger than the width of the bottom surface.

The light transmissive portion 31 may include an opening. The cross section of the opening OP may be similar in shape to the transmittance variable portion 33. The cross-section of the opening OP is not limited the aforementioned shape, and may take a trapezoidal, rectangular, square, or other polygonal shape.

The opening OP may be formed from the surface of the light transmissive portion 31.

One side of the transmittance variable portion 33 may come into contact with the adjacent high refractive index portion 32, while the other side may come into contact with the adjacent light transmissive portion 31. The lower surface of the transmittance variable portion 33 may come into contact with the light transmissive portion 31. The upper surface of the transmittance variable portion 33 may come into contact with the second electrode 40.

The light transmissive portion 31 may transmit light from the lower side to the upper side. The light transmissive portion 31 may include transparent materials. The light transmissive portion 31 may include materials that allow the transmission of light.

The light transmissive portion 31 may include a photoalignment polymer. Since the light transmissive portion 31 is formed by the curing of the aforementioned photoalignment polymer, the light transmissive portion 31 itself may be considered to contain the photoalignment polymer.

The light transmissive portion 31 may transmit light entering from the first substrate 10 or the second substrate 50 in a direction towards the other substrate.

For example, as illustrated in FIGS. 12 and 13, the light transmissive portion 31 may transmit a portion L1a of the provided first light L1 from the lower side of the first substrate 10 towards the upper side. Hereinafter, the mode with a limited lateral viewing angle depicted in FIG. 12 is referred to as first 1, and the mode with a wider lateral viewing angle depicted in FIG. 13 is referred to as second mode.

The transmittance variable portion 33 may include a dispersion liquid 33a and light-absorbing particles 33b. In more detail, the transmittance variable portion 33 is filled with a dispersion liquid 33a, a plurality of light-absorbing particles 33b may be dispersed within the dispersion liquid 33a.

The dispersion liquid 33a may be a substance that disperses the light-absorbing particles 33b. The dispersion liquid 33a may include transparent materials.

Light-absorbing particles 33b may be arranged in a dispersed manner within the dispersion liquid 33a. In more detail, the plurality of light-absorbing particles 33b may be arranged in a spaced-apart manner within the dispersion liquid 33a. The light-absorbing particles 33b may include a substance capable of absorbing light. The light-absorbing particles may have colors.

The transmittance variable portion 33 may vary the light transmittance via the light-absorbing particles 33b. In more detail, the transmittance variable portion 33 may change the light transmittance via the light-absorbing particles 33b, resulting in switching between a light-blocking portion to a light-transmitting portion. That is, the transmittance variable portion 33 may alter the light transmittance thereof by scattering and aggregating the light-absorbing particles 33b arranged within the dispersion liquid 33a.

For example, according to an aspect, the viewing angle control layer 250 may transition from the first mode to the second mode or from the second mode to the first mode by applying voltage to the first electrode 20 and the second electrode 40.

In more detail, according to an aspect, the viewing angle control layer 250 in the first mode operates in such a way that the transmittance variable portion 33 serves as a light-blocking portion to block light at predetermined angles. That is, the user's viewing angle (side viewing angle or horizontal viewing angle) from the outside may be narrowed.

Additionally, according to the aspect, the viewing angle control layer 250 in the second mode operates in such a way that the transmittance variable portion 33 serves as a light-transmitting portion, allowing light to pass through both the light transmissive portion 31 and the transmittance variable portion 33. That is, the viewing angle (side viewing angle or horizontal viewing angle) of the user looking from the outside may be widened.

The transition from the first mode to the second mode, i.e., switching the transmittance variable portion 33 from the light-blocking state to the light-transmitting state, may be achieved through the movement of the light-absorbing particles 33b within the transmittance variable portion 33. That is, the light-absorbing particles 33b have charges on their surfaces, and may be moved to the first electrode or the second electrode depending on the characteristics of the charges and the voltage applied to the electrodes. That is, the light-absorbing particles 33b may be electrophoretic particles.

The above description merely illustrates specific embodiments of the display apparatus.

Therefore, it should be noted that those skilled in the art may readily understand that the present disclosure may be substituted or modified in various forms within the scope of the claims below, without departing from the spirit of the disclosure.

A display apparatus disclosed in the present disclosure includes a cover window, an adhesive member positioned on an upper surface of the cover window, a display panel positioned on the adhesive member, and a guide holder positioned on an upper side of the display panel to cover the display panel, wherein the adhesive member may extend outward from the display panel.

The guide holder may contact the upper side of an extended portion of the adhesive member.

The guide holder may include a vertical portion and a horizontal portion, the vertical portion contacting the upper side of the extended portion of the adhesive member.

The guide holder may be retreated inward from the cover window.

The cover window may include a planar area defining the outermost edge, the adhesive member may be arranged inside the planar area of the cover window, and the display panel may be arranged inside the adhesive member.

The guide holder may include a vertical portion, a horizontal portion, and a stepped portion, the stepped portion contacting the upper side of the cover window and the upper side of the adhesive member.

The display apparatus may further include a viewing angle control layer arranged on the upper side of the adhesive member and a second adhesive member arranged between the viewing angle control layer and the display panel.

The second adhesive member may extend outward from the display panel and extend outward from the adhesive member.

The guide holder may contact the upper side of the cover window and the upper side of the second adhesive member.

The adhesive member may extend outward from the display panel and extend outward from the second adhesive member.

The guide holder may contact the upper side of the cover window and the upper side of the adhesive member.

The guide holder may further contact a lateral side of the second adhesive member.

The display apparatus may further include a backplate and a heat dissipation plate arranged on the upper side of the guide holder.

The guide holder may include a board support member supporting a control printed circuit board.

The display apparatus may further include a back cover arranged on the upper side of the guide holder, and the back cover may be screw-connected with the board support member and the control printed circuit board.

It will be apparent to those skilled in the art that various modifications and variations can be made in the display apparatus of the present disclosure without departing from the spirit or scope of the aspects. Thus, it is intended that the present disclosure covers the modifications and variations of the aspects provided they come within the scope of the appended claims and their equivalents.

What is claimed is:

1. A display apparatus comprising:
a cover window;
an adhesive member positioned on an upper surface of the cover window;
a display panel positioned on the adhesive member; and
a guide holder positioned on an upper side of the display panel to cover the display panel, wherein the adhesive member extends outward from the display panel.

2. The display apparatus of claim 1, wherein the guide holder contacts the upper side of an extended portion of the adhesive member.

3. The display apparatus of claim 2, wherein the guide holder includes a vertical portion and a horizontal portion, and the vertical portion contacting the upper side of the extended portion of the adhesive member.

4. The display apparatus of claim 1, wherein the guide holder is retreated inward from the cover window.

5. The display apparatus of claim 1, wherein the cover window includes a planar area defining the outermost edge, and
wherein the adhesive member is arranged inside the planar area of the cover window, and the display panel is arranged inside the adhesive member.

6. The display apparatus of claim 1, wherein the guide holder comprises a vertical portion, a horizontal portion, and a stepped portion, and
wherein the stepped portion contacts the upper side of the cover window and the upper side of the adhesive member.

7. The display apparatus of claim 1, further comprising:
a viewing angle control layer arranged on the upper side of the adhesive member; and
a second adhesive member arranged between the viewing angle control layer and the display panel.

8. The display apparatus of claim 7, wherein the second adhesive member extends outward from the display panel and extends outward from the adhesive member.

9. The display apparatus of claim 8, wherein the guide holder contacts the upper side of the cover window and the upper side of the second adhesive member.

10. The display apparatus of claim 7, wherein the adhesive member extends outward from the display panel and extends outward from the second adhesive member.

11. The display apparatus of claim 10, wherein the guide holder contacts the upper side of the cover window and the upper side of the adhesive member.

12. The display apparatus of claim 11, wherein the guide holder further contacts a lateral side of the second adhesive member.

13. The display apparatus of claim 1, further comprising a backplate and a heat dissipation plate arranged on the upper side of the guide holder.

14. The display apparatus of claim 1, wherein the guide holder includes a board support member supporting a control printed circuit board.

15. The display apparatus of claim 14, further comprising a back cover arranged on the upper side of the guide holder,
wherein the back cover is screw-connected with the board support member and the control printed circuit board.
